(19) United States
(12) Patent Application Publication
(10) Pub. No.: US 2004/0182544 A1
(43) Pub. Date: Sep. 23, 2004

(54) Cooling device utilizing liquid coolant

(76) Inventors: Hsieh Kun Lee, Tu-chen (TW); Lei Li, Shenzhen (CN); Cheng-Tien Lai, Tu-chen (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/620,636

(22) Filed: Jul. 15, 2003

(30) Foreign Application Priority Data
Dec. 27, 2002 (TW) 91221275

(51) Int. Cl. H05K 7/20

(52) U.S. Cl. 165/80.4; 361/699

(57) ABSTRACT

A cooling device utilizing liquid coolant includes a tank (10) and a cover (30) hermetically sealing the tank. The tank includes a base (11) and two pairs of sidewalls (122). A plurality of parallel inner walls (132) is formed in the tank thereby defining a channel for passage of the liquid coolant. A plurality of pins (15) is disposed in the channel. An inlet (102) and an outlet (104) are disposed at opposite ends of the channel for entry and exiting of the liquid coolant into and from the tank.

### BACKGROUND OF THE INVENTION

1. Field of the Invention

The present invention relates to cooling devices, and more particularly to a cooling device which utilizes liquid coolant for rapidly cooling an electronic package such as a central processing unit (CPU).

2. Description of Prior Art

During operating of an electronic device such as a computer central processing unti (CPU), a large amount of heat is often produced. The heat must be quickly removed from the CPU to prevent it from becoming unstable or being damaged. Typically, a cooling device is attached to an outer surface of the CPU to absorb heat from the CPU. The heat absorbed by the cooling device is then dissipated away from the cooling device by various means.

A conventional cooling device is disclosed in Taiwan Patent No. 486237. In this cooling device, liquid coolant is used to take away heat from the cooling device itself Referring to FIG. 3, the cooling device comprises a rectangular tank 22 covered by a cover 21. A reinforcing rib 23 is formed within the tank 22, the rib 23 spiralling from a central portion to a side extremity of the tank 22. The rib 23 thereby defines a channel 24 for passage of the coolant through the tank 22. The channel 24 comprises a beginning section 241 and a terminal section 242. The cover 21 forms an inlet 211 directed to the beginning section 241, and an outlet 212 directed to the terminal section 242. Coolant reaches the beginning section 241 via the inlet 211, flows along the channel 24, and then exits the cooling device via the outlet 212. Circulation of there coolant continuously removes heat from the cooling device.

However, contact between the coolant and the cooling device is limited on an inner surface of the cooling device and the rib 23. Therefore the heat absorbing capacity of the coolant is not fully utilized before it exits the cooling device. Secondly, because the channel 24 is spiralled, the coolant flows at different speeds through different sections of the channel 24. A speed of the coolant in a middle of the tank 22 is fastest; conversely, a speed of the coolant in other parts of the tank 22 may be too slow. While, the middle of the tank 22 corresponds to a middle of the electronic package, and must be adequately cooled. If the speed of the coolant in the middle of the tank 22 is too fast, the coolant is liable to flow through the middle of the tank 22 too quickly without being able to efficiently absorb heat accumulated thereat. If the coolant in the middle of the tank 22 is decelerated to get efficient heat absorbs thereat, the coolant in some parts of the tank 22 is liable to be static, thereby building up high temperatures thereat. These shortcomings of the cooling device reduce the efficiency of removal of heat from the cooling device, and subsequent transfer of heat from the electronic package to the cooling device.

An improved cooling device is desired to overcome the above-described disadvantages of the prior art.

### SUMMARY OF THE INVENTION

Accordingly, an object of the present invention is to provide a cooling device which quickly absorbs heat from an electronic package and quickly dissipates the absorbed heat.

In order to achieve the object set out above, a cooling device utilizing liquid coolant in accordance with a preferred embodiment of the present invention comprises a tank and a cover hermetically sealing the tank. The tank includes a base and two pairs of sidewalls. A plurality of parallel inner walls is formed in the tank thereby defining a channel for passage of the liquid coolant. A plurality of pins is disposed in the channel. An inlet and an outlet are disposed at opposite ends of the channel for entry and exiting of the liquid coolant into and from the tank.

Other objects, advantages and novel features of the present invention will become more apparent from the following detailed description when taken in conjunction with the accompanying drawings, in which:

### BRIEF DESCRIPTION OF THE DRAWINGS

FIG. 1 is an isometric view of a cooling device in accordance with the preferred embodiment of the present invention;

FIG. 2 is an exploded view of FIG. 1; and

FIG. 3 is an exploded, isometric view of a conventional cooling device.

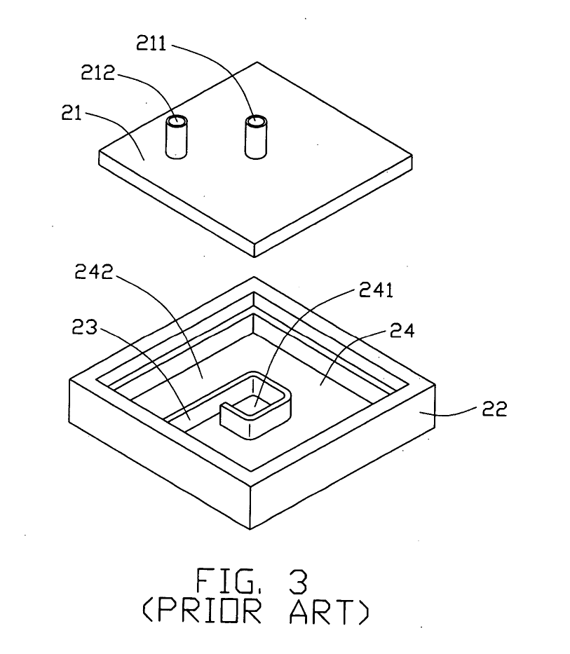

### DETAILED DESCRIPTION OF THE INVENTION

Reference will now be made to the drawing figures to describe the present invention in detail.

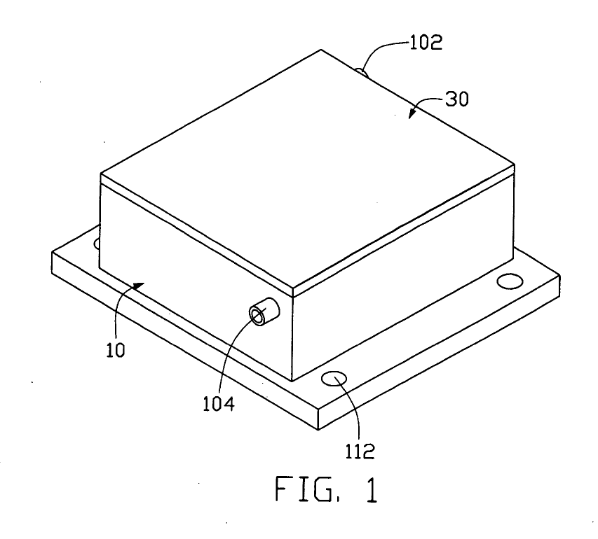

Referring to FIG. 1, a cooling device in accordance with the preferred embodiment of the present invention comprises a tank 10 and a cover 30. The cover 30 is hermetically mounted on the tank 10, thereby forming a closed device for heat exchange. The tank 10 forms an inlet 102 and an outlet 104 at opposite sides thereof respectively. Liquid coolant can enter the cooling device via the inlet 102 and exit the cooling device via the outlet 104.

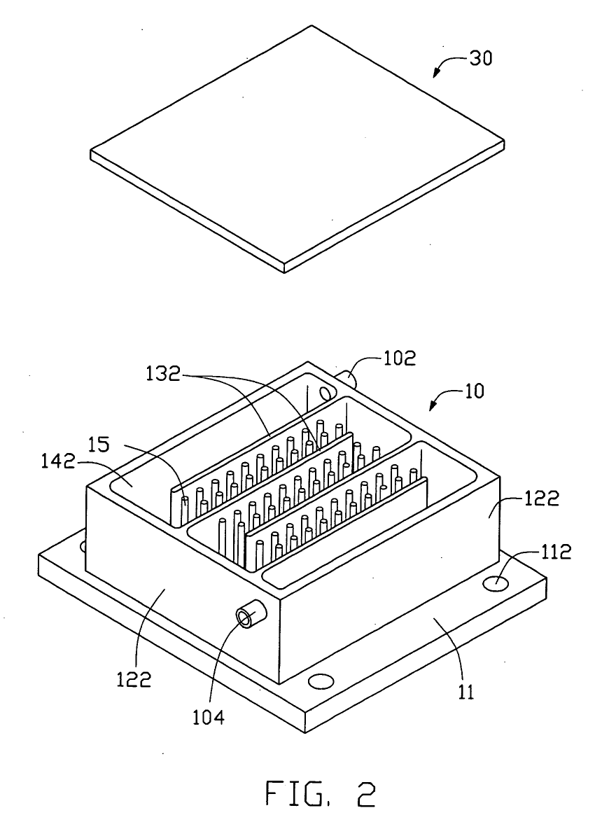

Referring to FIG. 2, the tank 10 has a bottom base 11. Four holes 112 are defined in four comers of the base 11 for positioning of the tank 10 on a supporting substrate. The base 11 is intimately attachable to an electronic package (not shown). Two pairs of sidewalls 122 extend perpendicularly upwardly from the base 11, whereby the tank 10 is substantially parallelepiped-shaped. In alternative embodiments of the present invention, the tank 10 can have other suitable shapes, such as being cylindrical.

A plurality of parallel, evenly spaced inner walls 132 is formed in the tank 10. The inner walls 132 extend alternately from one sidewall 122 and an opposite sidewall 122. A height of the inner walls 132 is equal to a height of the sidewalls 122. A distance between a free end of each inner wall 132 and a corresponding opposite sidewall 122 is substantially equal to a distance between any two adjacent inner walls 132. A zigzagged channel 142 having a substantially uniform width is thereby defined in the tank 10 between the inlet 102 and the outlet 104, for flow of the coolant from the inlet 102 to the outlet 104. As seen in FIG. 2, in the preferred embodiment of the present invention, the inlet 102 and the outlet 104 are disposed at opposite of the sidewalls 122 respectively. In alternative embodiments of the present invention, the inlet 102 and outlet 104 can be disposed at a pair of adjoining sidewalls 122, or at a same sidewall 122. When the inlet 102 and the outlet 104 are oriented at a same sidewall 122, an odd number of inner walls 132 is employed.

A plurality of pins 15 extends upwardly from the base 11 into the channel 142. As seen in FIG. 2, in the preferred embodiment of the present invention, the pins 15 are cylindrical. In alternative embodiments of the present invention, the pins 15 may be prism-shaped or have other suitable shapes. In the preferred embodiment of the present invention, a height of the pins 15 is substantially the same as the height of the sidewalls 122. In an alternative embodiment of the present invention, the height of the pins 15 is less than a height of the sidewalls 122.

In operation of the cooling device, heat is transferred from the electronic package (not shown) to the inner walls 132 and pins 15 of the base 11, and then conducted to the coolant to be carried away from the cooling device via the outlet 104. Because the channel 14 has a substantially uniform width throughout the tank 10, the coolant can efficiently traverse the channel 14 to provide speedy heat exchange with the inner walls 132 and pins 15.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A cooling device utilizing liquid coolant, comprising:
a tank comprising a plurality of parallel inner walls therein thereby defining a through channel for passage of the liquid coolant, a plurality of pins being disposed in the channel;
an inlet and an outlet disposed at opposite ends of the channel for entry and exiting of the liquid coolant into and from the tank; and
a cover hermetically sealing the tank.

2. The cooling device of claim 1, wherein the tank comprises a base, and two pairs of sidewalls perpendicularly extending from the base and surrounding the inner walls.

3. The cooling device of claim 2, wherein the inlet and the outlet are disposed at opposite sidewalls of the tank.

4. The cooling device of claim 2, wherein the inner walls perpendicularly extend from the base, and the inner walls and the sidewalls are substantially equal in height.

5. The cooling device of claim 2, wherein the inner walls extend alternately from one of the sidewalls and an opposite sidewall.

6. The cooling device of claim 5, wherein the inner walls are substantially uniformly spaced apart.

7. The cooling device of claim 6, wherein a distance between a free end of each of the inner walls and a corresponding opposite sidewall is substantially equal to a distance between any two adjacent inner walls.

8. The cooling device of claim 2, wherein the pins extend perpendicularly upwardly from the base.

9. The cooling device of claim 8, wherein a height of the pins is substantially equal to a height of the sidewalls.

10. The cooling device of claim 1, wherein each of the pins is cylindrical.

11. A cooling device comprising:
a tank including a base adapted to be in contact with a heat source;
a cover sealing the tank opposite to said base;
a horizontal sinuous channel defined in the tank;
working liquid filled in the channel; and
a plurality of small protrusions disposed in and along at least a portion of the channel for not only increasing heat transfer area between the working liquid and the tank but also resulting in turbulence for enhancement of heat exchange between the working liquid and the tank.

12. The cooling device of claim 11, wherein said tank includes opposite inlet and outlet respectively communicatively connected to two opposite ends of the channel.

13. The cooling device of claim 12, wherein the outlet and the inlet are substantially located on a periphery of the tank while the small protrusions are located around a center portion of the tank.

14. The cooling device of claim 11, wherein said cover is not integrally formed with the tank.

15. The cooling device of claim 11, wherein said small protrusions extend from the base.

16. The cooling device of claim 11, wherein said tank includes a plurality of inner walls forming said sinuous channel.

17. The cooling device of claim 11, wherein said small protrusions are pins.
